(19) United States
(12) Patent Application Publication
(10) Pub. No.: US 2026/0338476 A1
(43) Pub. Date: Oct. 29, 2026

(54) HEATING DEVICE

(71) Applicant: VAT Holding AG, Haag (CH)

(72) Inventor: Sven RIESCHL, Marlans (CH)

(73) Assignee: VAT Holding AG, Haag (CH)

(21) Appl. No.: 19/122,340

(22) PCT Filed: Oct. 13, 2023
(86) PCT No.: PCT/EP2023/078441

§ 371 Date: Apr. 18, 2025

(30) Foreign Application Priority Data
Oct. 19, 2022 (DE) 10 2022 127 528.0

(51) Int. Cl. F27B 17/00; F27D 7/06; F27D 11/00; H10P 72/00

(52) U.S. Cl. CPC F27B 17/0025; F27D 7/06; F27D 11/00; H10P 72/0432; F27D 2007/066

(57) ABSTRACT

A heating device (1) with a heating plate (2) for heating a workpiece (3), in particular a wafer, in a vacuum chamber (4). The heating plate (2) has a carrier layer (5) with an upper side (6), on which or above which the workpiece (3) can be arranged for heating, and the heating device (1) has a heating element (7) for heating the carrier layer (5) of the heating plate (2). The heating device (1) has fastening arms (9) arranged at an edge (8) of the heating plate (2) for fastening the heating plate (2) to supports (10) in the vacuum chamber (4), and the fastening arms (9) each have at least one elastically deflectable spring element (11) and a fastening device (12) for fastening the respective spring element (11) to the respective support (10).

### CROSS-REFERENCE TO RELATED APPLICATIONS

This application is a 371 National Phase of International Application PCT/EP2023/078441, filed Oct. 13, 2023, which claims priority from German Patent Application No. 10 2022 127 528.0, filed Oct. 19, 2022, both of which are incorporated herein by reference as if fully set forth.

### TECHNICAL FIELD

The present invention relates to a heating device and to a vacuum chamber with such a heating device.

### BACKGROUND

Heating devices of this type are known in the prior art. They are used to heat a workpiece such as, for example, a wafer in order thus to bring it to a temperature which is, for example, required in a subsequent treatment process. U.S. Pat. No. 6,551,448 B2 discloses a heating device with a heating plate for heating a workpiece.

### SUMMARY

The object of the invention is to improve generic heating devices such that they can particularly effectively compensate thermally induced changes in size of the heating plate without the possibility of thermally induced undesired tension occurring in the heating plate.

In order to achieve this object, the invention proposes a heating device having one or more of the features described herein.

It is thus provided according to the invention that the heating device has fastening arms, arranged at an edge of the heating plate, for fastening the heating plate on supports in the vacuum chamber, wherein the fastening arms in each case have at least one elastically deflectable spring element and a fastening device for fastening the respective spring element on the respective support.

Thermally induced changes in size of the heating plate can be compensated by fastening arms arranged at the edge of the heating plate and in particular by their elastically deflectable spring elements without undesired tension occurring within the heating device. The elastically deflectable spring elements are favorably designed as elongated. The elastic deflection of the spring elements favorably takes place transversely to their longitudinal extent. The elastically deflectable spring elements of the fastening arms are particularly preferably in each case designed as leaf springs. It is, however, in principle also possible for differently shaped elastically deflectable spring elements to be provided. The elastically deflectable spring elements are particularly preferably fastened with one end in each case at the edge of the heating plate, whilst the fastening device of the respective fastening arm is situated at the opposite end. It is particularly preferably provided that the spring elements are in each case elastically deflectable within a deflection plane running parallel to the top side of the carrier layer. It is, however, also favorable if the fastening arms protrude outward from the heating plate. Each fastening arm can have exactly one elastically deflectable spring element and exactly one fastening device. Variants are, however, also conceivable in which the fastening arm has two elastically deflectable spring elements, both of which lead to the same fastening device. Generally speaking, each fastening arm can have a plurality of elastically deflectable spring elements and/or a plurality of fastening devices.

There are likewise a wide range of different possible embodiments for the fastening device. In a particularly simple embodiment, the fastening device is a fastening eyelet through which the support itself or, for example, a fastening means such as a screw or a rivet can be passed in order to fasten the fastening device on the support. The fastening device can, however, for example, also be configured as a clamped connection, a screwed connection, and the like.

The fastening arms can be configured as single pieces or from multiple parts. The fastening arms or their elastically deflectable spring elements can be integrally molded with the heating plate. It is, however, also conceivable first to manufacture the fastening arms or their elastically deflectable spring elements as a separate component and then to fasten them to the heating plate by suitable means such as, for example, being screwed, riveted, soldered, welded, and the like. The same is true for the connection between the elastically deflectable spring element and the fastening device.

In order to be able to perform the said compensation of temperature-induced changes in size, it is particularly preferably provided that the spring elements in each case have a spring rate in the range from 30 N/mm to 100 N/mm, preferably from 50 N/mm to 80 N/mm. The spring constant here specifies, as is generally known, the ratio of the force acting on the spring element to the deflection of the spring element caused thereby. The deflection is here favorably measured in a direction orthogonal or radial to the adjacent edge of the heating plate.

There are a wide range of options for how the heating element can be designed to heat the carrier layer of the heating plate and thus also its top side. Particularly preferred variants of the invention provide that the heating element has a flat design and is arranged so that it lies on the carrier layer on the opposite side of the latter from the top side. The heating element can be, for example, a thick-film heating device in which an electric heating element is arranged flat between two glass plates. This heating element with a sandwich-type construction is favorably in direct contact, flat, with with that side of the carrier layer which is remote from the top side.

The heating plate can consist of just the carrier layer or be designed with multiple layers, even, for example, when the heating element is also designed as a further layer, fastened to the carrier layer, of the heating plate.

It is in any case favorable if the heating element is an electrically operated heating element. Particularly preferred variants then provide that electrical supply lines of the heating device are routed through at least one externally sealed tube to the heating element. As a result, electrical connection points by means of which the electrical supply lines are connected at the heating element can be kept permanently at atmospheric pressure, which contributes to the avoidance of electrical flashovers caused by the application of a vacuum in the vacuum chamber. The externally sealed tubes can be routed directly to the heating element or open into an externally sealed connection chamber in which the electrical connection points of the heating element are situated.

The carrier layer is preferably made from steel. It can, however, also be produced from an aluminum alloy or another correspondingly thermally conductive material.

During the heating process, the workpiece to be heated in each case can lie directly on the top side of the carrier layer of the heating plate or be arranged spaced apart above the top side of the carrier layer of the heating plate.

It is possible that the heating plate has recesses for the passage of lifting arms for lifting the respective workpiece from the top side of the carrier layer of the heating plate or for holding the respective workpiece above the top side of the carrier layer of the heating plate. In the case where the workpiece is arranged during the heating process slightly spaced apart above the top side of the carrier layer, it can thus lie, for example, on these lifting arms. The lifting arms are particularly preferably equipped with supporting balls, preferably made from glass, on which the workpiece can then be deposited.

The workpieces to be processed favorably have a plate-shaped design. In particular, it can be a so-called wafer.

The temperature generated by the heating element in the carrier layer and in particular at its top side is favorably regulated by a corresponding temperature regulator. With this in mind, it is favorable if the heating device has at least one temperature sensor for measuring the temperature of the carrier layer of the heating plate. This temperature value can then be fed as a measured value to a corresponding regulator of the heating element.

In addition to the heating device per se, the invention also relates to a vacuum chamber with at least one heating device according to the invention, wherein the vacuum chamber has a base plate and preferably at least three supports protruding from the base plate and arranged spaced apart from each other, and the heating plate of the at least one heating device is fastened, preferably exclusively, to the supports with the fastening devices of the fastening arms. The vacuum chamber can be a prechamber, an airlock chamber, but also a process chamber. The vacuum chamber is particularly preferably a prechamber into which the workpiece to be processed is introduced under atmospheric pressure and then, when the vacuum chamber is closed, the corresponding reduced pressure is generated, wherein the heating of the workpiece with the heating device can then take place simultaneously or subsequently. Vacuum chambers according to the invention can, however, of course also be process chambers in which other processing actions are carried out on the workpiece in addition to heating the workpiece.

Vacuum chambers are generally used when work needs to be carried out in a specific atmosphere and/or at a specific low pressure level. The term vacuum chamber is used in particular when work is carried out at pressure levels of less than or equal to 0.001 mbar (millibars) or 0.1 pascal. Vacuum chambers can, however, also be referred to when they are designed for pressures below normal pressure, i.e. below 1 bar.

A single heating device with a single heating plate can be provided in the vacuum chamber. It is, however, equally possible that the heating plates of two or more heating devices are arranged one above the other in the vacuum chamber. Vacuum valves for opening and closing the vacuum chamber, as well as transport devices for introducing the workpiece into the vacuum chamber and removing it therefrom are known per se in the prior art and do not have to be explained further here.

It is preferably provided that the fastening arms provided according to the invention serve not only to compensate thermally induced changes in size of the heating plate but also to ensure thermal insulation of the heating device from the base plate of the vacuum chamber. In this connection, it is favorably provided that, in the case of heating by means of the at least one heating device, a temperature difference of at least 100 °Celsius, preferably at least 200 °Celsius, exists between the base plate and the carrier layer of the heating plate of the at least one heating device. In order to achieve these values, the fastening arms and in particular the elastically deflectable spring elements of the fastening arms can have correspondingly small cross-sectional surface areas and/or be made from a correspondingly suitable thermally insulating material. In order to achieve this, there are numerous options which a person skilled in the art can configure as required.

### BRIEF DESCRIPTION OF THE DRAWINGS

Further features and details of preferred embodiments of the invention will be explained by way of example below on the basis of an exemplary embodiment. In the drawings:

FIG. 1 shows a schematic longitudinal section through a vacuum chamber according to the invention with two heating devices according to the invention arranged one above the other;

FIG. 2 shows the two heating devices from FIG. 1 in a perspective illustration obliquely from above;

FIG. 3 shows a plan view of the arrangement according to FIG. 2;

FIG. 4 shows an exploded illustration of FIG. 2, and

FIG. 5 shows a section along the line of section A-A from FIG. 3.

### DETAILED DESCRIPTION

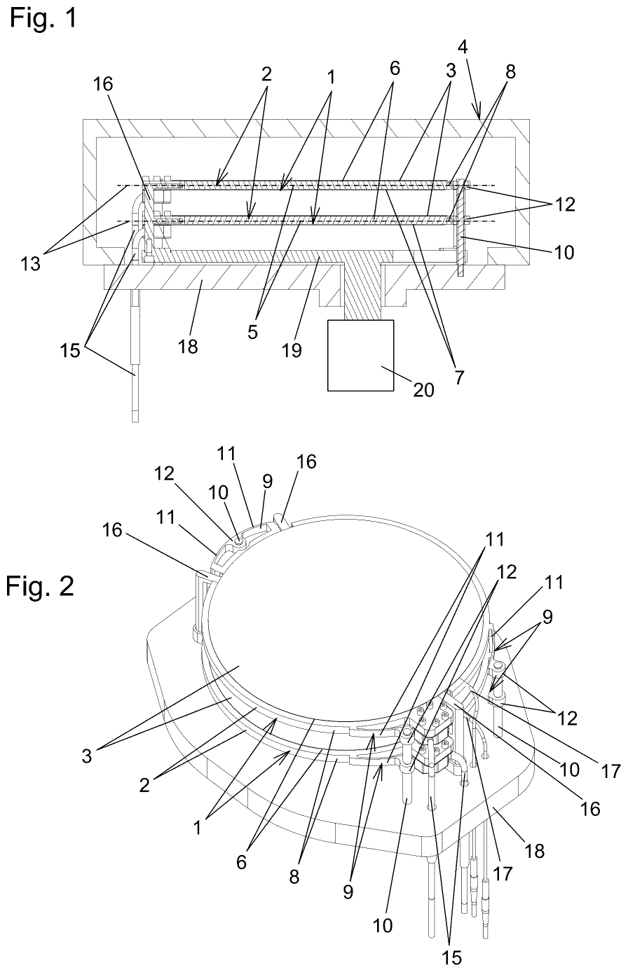

The longitudinal section, illustrated in FIG. 1, through the vacuum chamber 4 is shown in a highly schematic form. Only the base plate 18 of the vacuum chamber itself and the remainder of the housing can be seen in section. The vacuum valves for introducing the workpieces 3 into the vacuum chamber 4 and removing them therefrom are not illustrated, and pumping devices, process apparatuses, and the like which may be present are similarly not illustrated. These components which are not illustrated here can be designed as known per se in the prior art. This is also true for loading robots which introduce the workpieces 3 into the vacuum chamber 4 and also extract them therefrom again.

Two heating devices 1 arranged one above the other, with their heating plates 2, can be seen in FIG. 1. The heating plates 2 have in each case a carrier layer 5 with a top side 6. In order to be heated, the workpieces 3, for example in the form of wafers, are either placed directly on the respective top side 6 of the respective carrier layer 5 or arranged spaced apart above this top side 6 of the carrier layer 5. The carrier layer 5 is in any case heated by means of a heating element 7. In the present example, the heating elements 7 are in each case a so-called thick-film heating device, as has already been explained at the beginning and is known per se. The heating elements 7 in each case have a flat design and are arranged so that they lie on the carrier layer 5 on that side of the carrier layer 5 of the respective heating plate 2 which is opposite the top side 6. In addition to the heating devices 1, FIG. 1 also shows a linear actuator plate 19, on which lifting arms 16 are formed, which is arranged so that it can be raised and lowered in the vacuum chamber by means of a linear actuator 20 known per se and illustrated here only schematically. These lifting arms 16 can be raised and lowered by the linear actuator 20 together with the linear actuator plate 19. The lifting arms 16 serve, inter alia, to deposit the workpiece 3 on the top side 6 of the carrier layer 5 and to lift it again therefrom. The depositing takes place when the workpiece 3 needs to lie directly on the top side 6 of the carrier layer 5 during the heating process. If the workpiece 3 needs to be arranged slightly spaced apart above the top side 6 of the carrier layer 5 during the heating process, it can lie on the lifting arms 16 during the heating process, correspondingly spaced apart from the top side 6. It is particularly preferably provided that each of the lifting arms 16 has, as shown below, at least one ball 21, preferably made from glass, on which the workpieces 3 lie. The supports 10 to which the heating plates 2 are fastened with their fastening arms 9, as explained below in detail, are also illustrated in FIG. 1.

Furthermore, also shown in FIG. 1 are the tubes 15 through which are passed the electrical supply lines 14 for the heating element 7, designed here as an electrical heating element, of the respective heating device 1.

In the perspective illustration in FIG. 2, the upper part of the vacuum chamber 4 has now been removed such that only the base plate 18, the supports 10 fastened thereto, and the heating devices 1, fastened in turn to the supports 10, with their heating plates 2 can still be seen. According to the invention, it is in any case provided that each of the heating devices 1 has fastening arms 9, arranged at the respective edges 8 of the heating plate 2, for fastening the respective heating plate 2 to the supports 10 in the vacuum chamber 4. Each of the fastening arms 9 then has in each case at least one elastically deflectable spring element 11 and a fastening device 12 for fastening the respective spring element 11 to the respective support 10. The elastically deflectable spring elements 11 are, as illustrated here, preferably in each case designed as elongated as a type of leaf spring. In the exemplary embodiment shown here, the elastically deflectable spring elements 11 are in each case integrally molded with the respective edge of the respective heating plate 2. At their respective opposite ends are situated the fastening devices 12 which are configured here in this exemplary embodiment as simple fastening eyelets. Other types of fastening devices 12 could of course also be implemented in order to fasten the respective fastening arm 9 and thus the respective heating plate 2 to the respective support 10. They could, for example, be clamped or screwed connections or other types of fastening. There are of course also different options from those in the exemplary embodiment shown here for fastening the fastening arms 9 or the elastically deflectable spring elements 11 to the respective edge 8 of the respective heating plate 2. Instead of the fastening arms 9 or the elastically deflectable spring elements 11 being integrally molded, these components could also be screwed, riveted, soldered, welded, and/or otherwise fastened to the respective edge of the respective heating plate 2. FIG. 2 also illustrates that the fastening arms 9 can be designed differently. The fastening arms 9, which are illustrated in the bottom right in FIG. 2, in each case have a single elastically deflectable spring element 11, a single fastening device 12 of which is in each case situated at the end remote from the edge 8 of the respective heating plate 2. Illustrated in the top left in FIG. 2 is a variant of a fastening arm 9 in which the fastening device 12 is arranged between two elastically deflectable spring elements 11 and is fastened thereto. There are a wide range of options for this. It should in particular be pointed out that the elastically deflectable spring elements 11 could be configured as more or less straight, slightly curved, but also with a significantly more rounded or curved profile than is illustrated here.

It is in any case favorably provided, as also implemented here, that the spring elements 11 are in each case elastically deflectable within a deflection plane 13 running parallel to the top side 6 of the carrier layer 5. The position of the deflection planes 13 is indicated schematically in FIG. 1. It is also favorable if, as also implemented here, the fastening arms 9 in each case protrude outward from the heating plate 2.

Also visible in FIG. 2 are the measurement sensors 17 which are in each case attached to the corresponding carrier layer 5 in order to measure the temperature of the carrier layer 5 of the respective heating plate 2.

For the sake of completeness, it should be pointed out again at this point that in each case only one single heating device 1 according to the invention but also two or more heating devices 1 according to the invention can be arranged in the vacuum chambers 4 according to the invention. If there are two or more heating devices 1 according to the invention, they are favorably, as also illustrated here, arranged one above the other in the vacuum chamber 4.

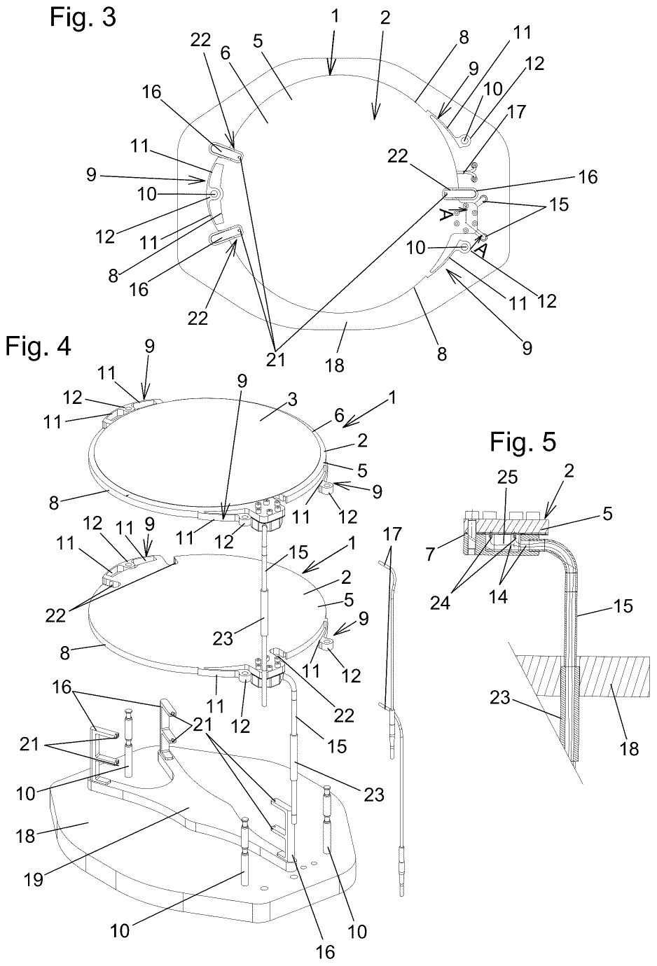

In FIG. 2, a workpiece 3 lies on each top side 6 of the respective carrier layer 5 of the respective heating plate 2. It can here be, for example, a wafer or a different plate-shaped workpiece 3. However, the workpieces 3 are not illustrated in the plan view in FIG. 3. It can be clearly seen here, as well as in the exploded illustration in FIG. 4, that the heating plates 2 in each case have recesses 22 for the passage of the lifting arms 16. Also visible in FIG. 3 are the balls 21 in the lifting arms 16. They are preferably glass balls. It is favorably provided that the workpiece 3 in each case lies on the lifting arm 16 with just the balls 21 interposed. If the lifting arms 16 are lowered correspondingly far enough by means of the linear actuator 20, the workpiece 3 then lies directly on the top side 6 of the carrier layer 5.

FIG. 4 shows the arrangement in FIG. 2 again in an exploded illustration in which the already described individual parts can be seen particularly well.

FIG. 5 shows the section along the line of section A-A in FIG. 3 through one of the externally sealed tubes 15 provided here, through which the electrical supply lines 14 for operation of the respective electrically operated heating element 7 are passed. It can be seen in FIG. 5 how the electrical feed lines 14 are in each case connected to the electrical heating element 7 by means of an electrical connection point 24. In FIG. 5, the electrical connection points 24 are situated in an externally sealed connection chamber 25 into which the externally sealed tubes 15 are routed. Alternatively, the tubes 15 could, however, also be routed directly to the electrical connection points 24 such that corresponding connection chambers 25 could also be omitted.

For the sake of completeness, it should also be pointed out that the tubes 15 can also be designed, as illustrated here, as corrugated tubing 23 in some portions. Thermally induced expansion and displacement of the tubes 15 can be compensated by such corrugated tubing 23.

### KEY TO THE REFERENCE SIGNS

1 heating device
2 heating plate
3 workpiece
4 vacuum chamber
5 carrier layer
6 top side
7 heating element
8 edge
9 fastening arm
10 support
11 spring element
12 fastening device
13 deflection plane
14 electrical supply line
15 tube
16 lifting arm
17 temperature sensor
18 base plate
19 linear actuator plate
20 linear actuator
21 ball
22 recess
23 corrugated tubing
24 electrical connection point
25 connection chamber

1. A heating device, comprising:
a heating plate for heating a workpiece in a vacuum chamber, the heating plate having a carrier layer with a top side on or above which the workpiece is adapted to be arranged in order to be heated;
a heating element for heating the carrier layer of the heating plate;
fastening arms arranged at an edge of the heating plate for fastening the heating plate on supports in the vacuum chamber, and the fastening arms in each case have at least one elastically deflectable spring element and a fastening device for fastening the respective spring element on a respective one of the supports.

2. The heating device as claimed in claim 1, wherein the spring elements are in each case elastically deflectable within a deflection plane running parallel to the top side of the carrier layer.

3. The heating device as claimed in claim 1, wherein the fastening arms protrude outward from the heating plate.

4. The heating device as claimed in claim 1, wherein the spring elements each have a spring rate in a range from 30 N/mm to 100 N/mm.

5. The heating device as claimed in claim 1, wherein heating element is flat and is arranged on the carrier layer on an opposite side of the carrier layer from the top side.

6. The heating device as claimed in claim 1, wherein the heating element is an electrically operated heating element and electrical supply lines are routed through at least one externally sealed tube to the heating element.

7. The heating device as claimed in claim 1, wherein the heating plate has recesses for passage of lifting arms for lifting the respective workpiece from the top side of the carrier layer of the heating plate or for holding the respective workpiece above the top side of the carrier layer of the heating plate.

8. A vacuum chamber comprising:
at least one of the heating devices as claimed in claim 1;
a base plate and supports protruding from the base plate and arranged spaced apart from each other; and
the heating plate of the at least one heating device is fastened to the supports with the fastening devices of the fastening arms.

9. The vacuum chamber as claimed in claim 8, wherein the heating plates of two or more of the heating devices are arranged one above the other in the vacuum chamber.

10. The vacuum chamber as claimed in claim 8, wherein in the case of heating by the at least one heating device, a temperature difference of at least 100 °Celsius, exists between the base plate and the carrier layer of the heating plate of the at least one heating device.

11. The heating device of claim 1, further comprising at least one temperature sensor for measuring the temperature of the carrier layer of the heating plate.
